(19) United States
(12) Patent Application Publication
(10) Pub. No.: US 2026/0020453 A1
(43) Pub. Date: Jan. 15, 2026

(54) DISPLAY PANEL AND DISPLAY DEVICE

(71) Applicants: CHONGQING BOE DISPLAY TECHNOLOGY CO., LTD., Chongqing (CN); BOE TECHNOLOGY GROUP CO., LTD., Beijing (CN)

(72) Inventors: Jie Li, Beijing (CN); Dawei Shi, Beijing (CN); Wei Zhang, Beijing (CN); Zhijian Qi, Beijing (CN); Binbin Ma, Beijing (CN); Tongwei Xu, Beijing (CN)

(73) Assignees: CHONGQING BOE DISPLAY TECHNOLOGY CO., LTD., Chongqing (CN); BOE TECHNOLOGY GROUP CO., LTD., Beijing (CN)

(21) Appl. No.: 18/992,689

(22) PCT Filed: May 28, 2024
(86) PCT No.: PCT/CN2024/095828

§ 371 Date: Jan. 9, 2025

(30) Foreign Application Priority Data
Jun. 2, 2023 (CN) 202310653203.X

(51) Int. Cl. H10K 59/131

(52) U.S. Cl. CPC H10K 59/131

(57) ABSTRACT

The present application provides a display panel and a display device. The present application arranges a plurality of compensation wirings in a second active area located on at least one side of the light-transmitting active area in a second direction, by coupling these compensation wirings with first pixel circuits in the second active area and second pixel circuits, a coupling environment at a position where the compensation wirings are arranged in the second active area is similar to a coupling environment at a position where conductive wires are arranged in a first active area, solving a problem of a display difference between the first active area and the second active area, effectively improving a defect of uneven display in the first active area and the second active area, and enhancing the display image quality.

### CROSS-REFERENCE TO RELATED APPLICATIONS

The present application claims the priority of the Chinese patent application filed on Jun. 2, 2023 before the CNIPA, China National Intellectual Property Administration with the application number of 202310653203.X and the title of “DISPLAY PANEL AND DISPLAY DEVICE”, which is incorporated herein in its entirety by reference.

### TECHNICAL FIELD

The present application relates to the technical field of displaying and more particularly, to a display panel and a display device.

### BACKGROUND

With the rapid development of the OLED (Organic Light-Emitting Diode) industry and the increasing demand for ultimate graphics from users, full screen technology has emerged. The design of a full screen inevitably needs to consider the display effect of the front camera area. In related art, a plurality of ITO (indium tin oxide) wirings are arranged in the FDC (Full Display with Camera) area under the screen where the front camera area is located and beside it, to improve the light transmission effect in the front camera area.

### SUMMARY

The present application provides a display panel and a display device. The present application provides a display panel, the display panel includes an active area and a peripheral area surrounding the active area, the active area includes a light-transmitting active area, and a first active area located on at least one side of the light-transmitting active area along a first direction and a second active area located on at least one side of the light-transmitting active area along a second direction, the first direction and the second direction intersect, light transmittance of the light-transmitting active area is greater than light transmittance of the active area; the display panel further includes:
a substrate;
a plurality of first light-emitting elements and a plurality of first pixel circuits, located on a side of the substrate and located in the first active area and the second active area, wherein the plurality of first pixel circuits are configured for driving the plurality of first light-emitting elements to emit light, and orthographic projections of the plurality of first pixel circuits on the substrate at least partially overlap with orthographic projections of the plurality of first light-emitting elements on the substrate;
a plurality of second pixel circuits, located on the side of the substrate, and located in the first active area;
a plurality of second light-emitting elements, located on the side of the substrate, and located in the light-transmitting active area, wherein the plurality of second pixel circuits are configured for driving the plurality of second light-emitting elements to emit light;
a plurality of conductive wires, located on the side of the substrate and located in the first active area, wherein the plurality of conductive wires connect the plurality of second pixel circuits and the plurality of second light-emitting elements; and
a plurality of compensation wirings, located on the side of the substrate and located in the second active area, wherein orthographic projections of the plurality of compensation wirings on the substrate overlap with the orthographic projections of the plurality of first pixel circuits on the substrate.

In some implementations, lengths of the plurality of compensation wirings in the first direction decrease sequentially along the second direction away from the light-transmitting active area.

In some implementations, a length difference between adjacent compensation wirings among the plurality of compensation wirings is equal.

In some implementations, lengths of the plurality of compensation wirings in the first direction are equal.

In some implementations, the display panel further includes at least one flat layer located on a side of the plurality of first pixel circuits and the plurality of second pixel circuits away from the substrate;
the plurality of compensation wirings located on a side of the at least one flat layer away from the substrate; and
the plurality of first light-emitting elements and the plurality of second light-emitting elements located on a side of the plurality of compensation wirings away from the substrate.

In some implementations, the at least one flat layer includes three flat layers including a first flat layer, a second flat layer and a third flat layer; the first flat layer, the second flat layer and the third flat layer are arranged in stacked along a direction away from the substrate; and
the plurality of compensation wirings are located on a side of the first flat layer away from the substrate, located on a side of the second flat layer away from the substrate, and located on a side of the third flat layer away from the substrate, respectively.

In some implementations, shortest distances from an orthographic projection of a compensation wiring located on the side of the first flat layer away from the substrate on the substrate, an orthographic projection of a compensation wiring located on the side of the second flat layer away from the substrate on the substrate, and an orthographic projection of a compensation wiring located on the side of the third flat layer away from the substrate on the substrate to the light-transmitting active area decrease sequentially; or
the shortest distances from the orthographic projection of the compensation wiring located on the side of the first flat layer away from the substrate on the substrate, the orthographic projection of the compensation wiring located on the side of the second flat layer away from the substrate on the substrate, and the orthographic projection of the compensation wiring located on the side of the third flat layer away from the substrate on the substrate to the light-transmitting active area increase sequentially.

In some implementations, a quantity of compensation wirings located on the side of the first flat layer away from the substrate, a quantity of compensation wirings located on the side of the second flat layer away from the substrate, and a quantity of compensation wirings located on the side of the third flat layer away from the substrate are equal.

In some implementations, lengths, in the first direction, of compensation wirings arranged on a side of a same flat layer away from the substrate are equal; and
lengths, in the first direction, of compensation wirings arranged on sides of different flat layers away from the substrate decrease sequentially along the second direction away from the light-transmitting active area.

In some implementations, a spacing between two adjacent compensation wirings among the plurality of compensation wirings increases sequentially along the second direction away from the light-transmitting active area.

In some implementations, each compensation wiring among the plurality of compensation wirings includes a plurality of line segment wirings, and a spacing between any two adjacent line segment wirings in a same compensation wiring is equal.

In some implementations, the orthographic projections of the plurality of compensation wirings on the substrate are located between the orthographic projections of the plurality of first light-emitting elements on the substrate; or
the orthographic projections of the plurality of compensation wirings on the substrate overlap with the orthographic projections of the plurality of first light-emitting elements on the substrate.

In some implementations, the plurality of compensation wirings are arranged in parallel in the first direction.

In some implementations, the plurality of compensation wirings are made of transparent indium tin oxide.

In some implementations, the first active area is located on two sides of the light-transmitting active area along the first direction, and the second active area is located on two sides of the light-transmitting active area along the second direction; and
the plurality of compensation wirings are located in the second active area on the two sides of the light-transmitting active area.

In some implementations, lengths, in the first direction, of compensation wirings in the second active area located on any one side of the light-transmitting active area decrease sequentially along the second direction away from the light-transmitting active area.

In some implementations, the plurality of conductive wires are located in the first active area on the two sides of the light-transmitting active area.

In some implementations, the light-transmitting active area has a symmetrical axis along the first direction, the plurality of compensation wirings respectively located on the two sides of the light-transmitting active area along the second direction are symmetrically arranged with respect to the symmetrical axis.

Based on the same concept, the present application also provides a display device, including the display panel according to any one of the above implementations.

In some implementations, the display device further includes a sensor located on a side of a non-display surface of the display panel, and an orthographic projection of the sensor on the display panel overlaps with an orthographic projection of the light-transmitting active area of the display panel on the display panel.

It can be seen from the above that, the present application provides a display panel and a display device. By arranging a plurality of compensation wirings in a second active area located on at least one side of the light-transmitting active area in a second direction, and by coupling these compensation wirings with first pixel circuits in the second active area and second pixel circuits, a coupling environment at a position where the compensation wirings are arranged in the second active area is similar to a coupling environment at a position where conductive wires are arranged in a first active area, solving a problem of a display difference between the first active area and the second active area, effectively improving a defect of uneven display in the first active area and the second active area, and enhancing the display image quality.

### BRIEF DESCRIPTION OF THE DRAWINGS

In order to more clearly illustrate the technical solutions of the embodiments of the present application or the related art, the figures that are required to describe the embodiments or the related art will be briefly described below. Apparently, the figures that are described below are some embodiments of the present application, and a person skilled in the art may obtain other figures according to these figures without paying creative work.

FIG. 1 is a schematic structural diagram of a display panel in related art according to an embodiment of the present application;

FIG. 2 is a schematic diagram of a partial structure of a display panel in related art according to an embodiment of the present application;

FIG. 3 is a schematic diagram of a pixel circuit arrangement of a display panel in related art according to an embodiment of the present application;

FIG. 4 is a schematic diagram of uneven display defects in a FDC area of a display panel in related art according to an embodiment of the present application;

FIG. 5A is a schematic diagram of a partial structure of a light-transmitting active area, located at a first position, of a first exemplary display panel according to an embodiment of the present application;

FIG. 5B is a schematic diagram of a partial structure of a light-transmitting active area, located at a second position, of a first exemplary display panel according to an embodiment of the present application;

FIG. 5C is a schematic diagram of a partial specific structure of a light-transmitting active area, located at a second position, of a first exemplary display panel according to an embodiment of the present application;

FIG. 6A is a schematic diagram of a partial structure of a second exemplary display panel according to an embodiment of the present application;

FIG. 6B is a schematic diagram of a partial specific structure of a second exemplary display panel according to an embodiment of the present application;

FIG. 7A is a schematic diagram of a partial structure of a third exemplary display panel according to an embodiment of the present application;

FIG. 7B is a schematic diagram of a partial specific structure of a third exemplary display panel according to an embodiment of the present application;

FIG. 8 is a schematic diagram of a partial sectional structure of an exemplary display panel according to an embodiment of the present application;

FIG. 9A is a schematic diagram of a partial structure of a fourth exemplary display panel according to an embodiment of the present application;

FIG. 9B is a schematic diagram of a partial sectional structure along a section line H in FIG. 9A;

FIG. 10A is a schematic diagram of a partial structure of a fifth exemplary display panel according to an embodiment of the present application;

FIG. 10B is a schematic diagram of a partial sectional structure along a section line H in FIG. 10A;

FIG. 11A is a schematic diagram of a partial structure of a sixth exemplary display panel according to an embodiment of the present application;

FIG. 11B is a schematic diagram of a partial specific structure of a sixth exemplary display panel according to an embodiment of the present application;

FIG. 12A is a schematic diagram of a partial structure of a seventh exemplary display panel according to an embodiment of the present application;

FIG. 12B is a schematic diagram of a partial specific structure of a seventh exemplary display panel according to an embodiment of the present application;

FIG. 13 is a schematic diagram of a partial structure of a projection of conductive wires of an exemplary display panel on a luminescent layer according to an embodiment of the present application;

FIG. 14A is a schematic diagram of a partial structure of an eighth exemplary display panel according to an embodiment of the present application;

FIG. 14B is a schematic diagram of a partial specific structure of an eighth exemplary display panel according to an embodiment of the present application;

FIG. 14C is a schematic diagram of a partial sectional structure along a section line H in FIG. 14A;

FIG. 15 is an equivalent circuit diagram of pixel circuits according to an embodiment of the present application;

FIG. 16 is a schematic diagram of working timing of the pixel circuits provided in FIG. 15;

FIG. 17A is a schematic diagram of a top view structure of a display panel after formation of a semiconductor layer in a circuit structure layer of a light-transmitting active area according to an embodiment of the present application;

FIG. 17B is a schematic diagram of a top view structure of a display panel after formation of a first gate metal layer in a circuit structure layer of a light-transmitting active area according to an embodiment of the present application;

FIG. 17C is a schematic diagram of a top view structure of a display panel after formation of a second gate metal layer in a circuit structure layer of a light-transmitting active area according to an embodiment of the present application;

FIG. 17D is a schematic diagram of a top view structure of a display panel after formation of a third insulation layer in a circuit structure layer of a light-transmitting active area according to an embodiment of the present application;

FIG. 17E is a schematic diagram of a top view structure of a display panel after formation of a first source-drain metal layer in a circuit structure layer of a light-transmitting active area according to an embodiment of the present application; and

FIG. 18 is a schematic structural diagram of a display device according to an embodiment of the present application.

### DETAILED DESCRIPTION

In order to make the purpose, technical solution, and advantages of this specification clearer and more understandable, the following will provide further detailed explanations of this specification in conjunction with specific embodiments and with reference to the accompanying drawings.

It should be noted that, unless otherwise defined, the technical or scientific terms used in the embodiments of the present application should have the usual meanings understood by those with general skills in the field to which the present application belongs. The terms “first”, “second”, and similar words used in the embodiments of the present application do not indicate any order, quantity, or importance, but are only used to distinguish different components. Words such as “including” or “comprising” refer to the elements, objects, or method steps that appear before the word, including the elements, objects, or method steps listed after the word and their equivalents, without excluding other elements, objects, or method steps. Words like “connection” or “connected” are not limited to physical or mechanical connections, but may include electrical connections, whether direct or indirect. “Up”, “down”, “left”, “right”, etc. are only used to represent relative positional relationships. When the absolute position of the described object changes, the relative positional relationship may also change accordingly.

In related art, the OLED (Organic Light-Emitting Diode) display screen is a display screen made of organic electroluminescent diodes. Due to its self-luminous organic electroluminescent diodes, the OLED display screen has excellent characteristics such as no need for backlight, high contrast, a thin thickness, a wide viewing angle, a fast reaction speed, capable to be used for flexible panels, a wide range of usage temperatures, and simple structure and process. With the increasing demand for images from users, full screen technology has emerged. The corresponding under-screen camera technology and light-transmitting display of the under-screen camera area have become the core technology of the full screen technology.

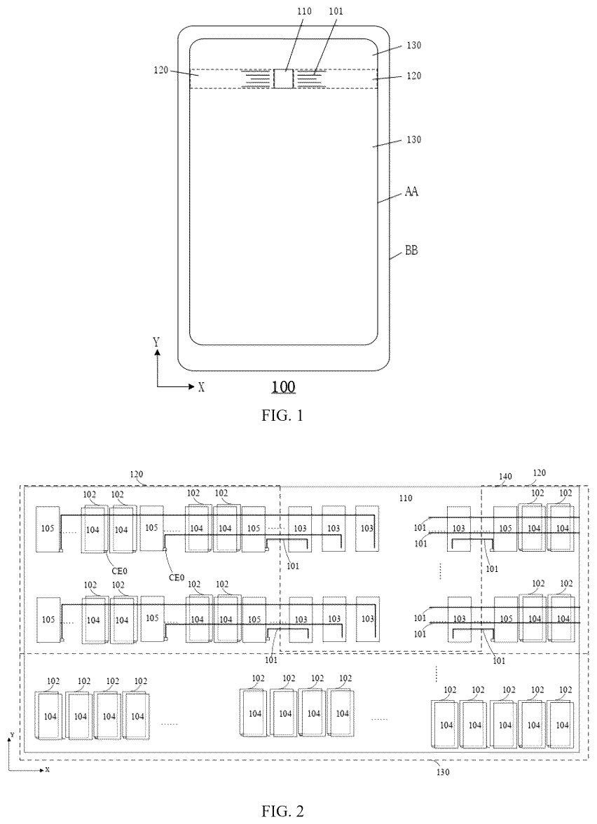

As shown in FIG. 1, the display panel 100 includes an active area AA and a peripheral area BB surrounding the active area AA, the active area AA may include a light-transmitting active area 110 (i.e. FDC area). In the active area AA, a part located on at least one side of the light-transmitting active area 110 along a first direction X is a first active area 120, and a part located on at least one side of the light-transmitting active area 110 along a second direction Y is a second active area 130. Among them, the first active area 120 and the second active area 130 at least partially surround the light-transmitting active area 110 (i.e. FDC area), while the second active area 130 is an active area within the active area AA except for the first active area 120 and the light-transmitting active area 110. As shown in FIG. 1, taking a rectangular display panel and the light-transmitting active area 110 in the middle and upper part of the active area AA as an example. The first active area 120 and the second active area 130 extend laterally along the display panel 100, and the second active area 130 is divided into an upper part and a lower part by the first active area 120 in a longitudinal direction of the display panel 100. By installing a plurality of conductive wires (ITO wiring) 101 of multiple layers in the first active area 120, light-transmitting display is achieved in the light-transmitting active area 110.

As shown in FIG. 2, a schematic diagram of the pixel circuits and the light-emitting elements of a part of the light-transmitting active area 110, the first active area 120, and the second active area 130 is shown. Among them, it includes the first light-emitting element 102 located in the first active area 120 and the second light-emitting element 103 located in the light-transmitting active area 110, which are arranged on the substrate 140. Since the light-emitting elements need to be controlled by the pixel circuits, the first light-emitting element 102 is driven by the first pixel circuit 104, and the second light-emitting element 103 is driven by the second pixel circuit 105. As shown in FIG. 2, the light-transmitting active area 110 only has the second light-emitting element 103, and its corresponding second pixel circuit 105 is arranged in the first active area 120, and then, the second light-emitting element 103 is connected to the second pixel circuit 105 through conductive wires (such as ITO wiring) 101, thereby arranging a plurality of conductive wires 101 in the first active area 120. Among them, each pixel circuit is connected to the light-emitting component through the connecting element CE0. A conductive wire 101 passes through the area where the pixel circuit of the pixel unit is located to connect the second pixel circuit 105 and the second light-emitting element 103 that are on two sides of this pixel unit, respectively. For example, the area where the pixel circuit of the pixel unit is located overlaps with the plurality of conductive wires 101 passing through that area. As shown in FIG. 2, taking one first pixel circuit 104 being capable to overlap with at most two conductive wires 101 as an example, in other embodiments, one first pixel circuit 104 may also overlap with more conductive wires 101. For example, in some embodiments, one first pixel circuit 104 may overlap with 10 to 15 conductive wires 101.

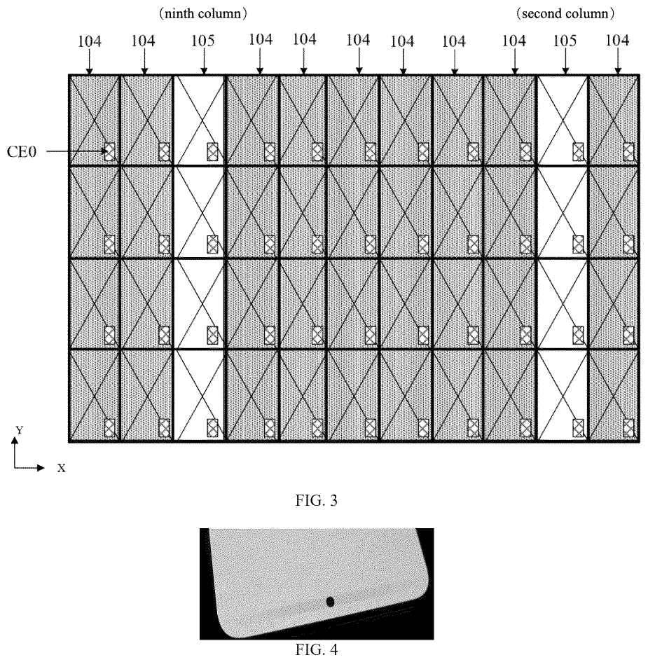

As shown in FIG. 3, in the first active area 120 and the second active area 130, every

two columns of the second pixel circuits 105 are arranged at an interval of set number of columns of the first pixel circuits 104. For example, the number of columns of the first pixel circuits 104 between two adjacent columns of the second pixel circuits 105 may be determined as needed. However, adding the conductive wires 101 in the first active area 120 increases the coupling phenomenon with the first pixel circuit 104 at lower layer and the second pixel circuit 105, resulting in significant display differences between the first active area 120 and the adjacent second active area 130, and resulting in severe Mura in the first active area 120. As shown in FIG. 4, the display effect of the product needs to be improved.

Based on the above actual situation, the embodiment of the present application provides a display panel. The present application effectively improves the Hole Mura in the FDC area and improves the image quality of the product by arranging a plurality of compensation wirings in the second active area on two sides of the first active area on the substrate.

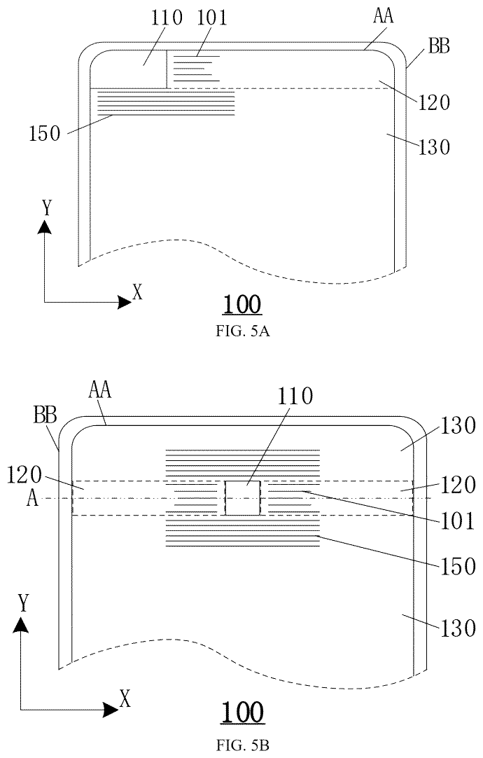

As shown in FIG. 5A to FIG. 5C, a schematic diagram of a partial structure of a display panel according to an embodiment of the present application is shown. The display panel 100 of the embodiment of the present application includes an active area AA and a peripheral area BB surrounding the active area AA, the active area AA includes a light-transmitting active area 101, and a first active area 120 located on at least one side of the light-transmitting active area 110 along a first direction X and a second active area 130 located on at least one side of the light-transmitting active area 110 along a second direction Y, the first direction X and the second direction Y intersect, and light transmittance of the light-transmitting active area 110 is greater than light transmittance of the active area AA. The display panel 100 further includes: a substrate 140; a plurality of first light-emitting elements 102 and a plurality of first pixel circuits 104, located on a side of the substrate 140 and located in the first active area 120 and the second active area 130, wherein the plurality of first pixel circuits 104 are configured for driving the plurality of first light-emitting elements 102 to emit light, and orthographic projections of the plurality of first pixel circuits 104 on the substrate 140 at least partially overlap with orthographic projections of the plurality of first light-emitting elements 102 on the substrate 140; a plurality of second pixel circuits 105, located on the side of the substrate 140, and located in the first active area 120; a plurality of second light-emitting elements 103, located on the side of the substrate 140, and located in the light-transmitting active area 110, wherein the plurality of second pixel circuits 105 are configured for driving the plurality of second light-emitting elements 103 to emit light; a plurality of conductive wires 101, located on the side of the substrate 140 and located in the first active area 120, wherein the plurality of conductive wires 101 connect the plurality of second pixel circuits 105 and the plurality of second light-emitting elements 103; and a plurality of compensation wirings 150, located on the side of the substrate 140 and located in the second active area 130, wherein orthographic projections of the plurality of compensation wirings 150 on the substrate 140 overlap with the orthographic projections of the plurality of first pixel circuits 104 on the substrate 140.

In some embodiments, as shown in FIG. 5A and FIG. 5B, the light-transmitting active area 110 may be located at any position of the active area AA, as shown in FIG. 5A, located at a corner of the active area AA, or intersecting with an edge of the active area AA, etc. Alternatively, as shown in FIG. 5B, it may be located in the middle of the active area AA. Meanwhile, in some embodiments, the shape of the light-transmitting active area 110 may be a regular circular area, square area, or a specific shape area designed according to the specific display panel structure. Its main purpose is to enable other structures in the display panel to obtain external light or images through the light-transmitting active area 110 without affecting the display effect of the entire active area AA. In specific application scenarios, any active area that meets the above purpose may be considered as the light-transmitting active area 110.

The first active area 120 is located on at least one side of the light-transmitting active area 110 along the first direction X, while the second active area 130 is located on at least one side of the light-transmitting active area 110 along the second direction Y. For example, as shown in FIG. 5B, the entire active area AA of the display panel 100 is divided into five parts, namely the light-transmitting active area 110, the first active area 120 located on the left side and the right side of the light-transmitting active area 110, and the second active area 130 located on the upper side and the lower side of the light-transmitting active area 110. Since the rectangular structure of the display panel 100, in some embodiments, the first direction X may be the lateral direction of the display panel 100 and the second direction Y may be the longitudinal direction of the display panel 100. The first direction X intersects with the second direction Y, and the first direction X is consistent with the wiring direction of the conductive wires 101 within the first active area 120.

As shown in FIG. 5C, it is a specific structural schematic diagram of the display panel 100 taking the light-transmitting active area 110 located in the middle of the active area AA. Among them, the substrate 140 is a load-bearing structure used to bear a plurality of functional structural layers of the display panel 100. Due to the substrate 140 belonging to the display panel 100, the first active area 120 and the second active area 130 are also divided on the substrate 140. At this time, since the light-transmitting active area 110 is located in the middle of the active area AA, there are two first active areas 120 and two second active areas 130.

As shown in FIG. 5C, the plurality of first light-emitting elements 102 and the plurality of first pixel circuits 104, as well as the plurality of second light-emitting elements 103 and the plurality of second pixel circuits 105, are respectively arranged on the substrate 140. Among them, the plurality of first pixel circuits 104 are configured for driving the plurality of first light-emitting elements 102 to emit light, and the plurality of second pixel circuits 105 are configured for driving the plurality of second light-emitting elements 103 to emit light. Since the second pixel circuits 105 are separately arranged from and the second light-emitting elements 103, the plurality of conductive wires 101 are provided to connect the second pixel circuits 105 and the second light-emitting elements 103. At this time, since the plurality of conductive wires 101 provided will couple with and the first pixel circuits 104 and the second pixel circuits 105, the plurality of compensation wirings 150 may be arranged on the second active area 130 on two sides of the first active area 120. By coupling the compensation wirings 150 with the first pixel circuits 104 and/or the second pixel circuits 105, a coupling environment at a position where the compensation wirings 150 are arranged in the second active area 130 is similar to a coupling environment at a position where the conductive wires 101 are arranged in the first active area 120, to solve a problem of a display difference between the first active area 120 and the second active area 130, effectively improve a defect of uneven display in the first active area 120 and the second active area 130, and enhance the display image quality.

In some embodiments, the compensation wirings 150 may overlap with the first pixel circuits 104 located in the second active area 130. One first pixel circuit 104 may overlap with a plurality of compensation wirings 150 or with only one compensation wiring 150. These compensation wirings 150 may be arranged parallel to each other, or not all of them may be arranged parallel to each other. They may be adjusted appropriately according to the specific application scenario, or the specific structures of the display panel and the substrate, such as arranging one or several compensation wirings 150 to be bent or at a certain angle with other compensation wirings 150. And if there are compensation wirings 150 on the two sides of the first active area 120, these compensation wirings 150 do not necessarily need to have a corresponding relationship with each other, for example, the compensation wirings 150 on the two sides may not be symmetrically arranged, etc. They may also be adjusted appropriately according to specific application scenarios, or the specific structures of the display panel and the substrate.

It can be seen from the above that, the present application provides a display panel. By arranging the plurality of compensation wirings in the second active area located on at least one side of the light-transmitting active area in the second direction, and by coupling these compensation wirings with the first pixel circuits in the second active area and the second pixel circuits, the coupling environment at the position where the compensation wirings are arranged in the second active area is similar to the coupling environment at the position where the conductive wires are arranged in the first active area, solving the problem of the display difference between the first active area and the second active area, effectively improving the defect of uneven display in the first active area and the second active area, and enhancing the display image quality.

In some embodiments, by coupling the compensation wirings 150 with the first pixel circuits 104 in the second active area 130 and the second pixel circuits 105, the coupling environment of the compensation wirings 150 as well as the first pixel circuits 104 and the second pixel circuits 105 is the same as or similar to the coupling environment of the conductive wires in the first active area 120 as well as the first pixel circuits 104 and the second pixel circuits 105, to solve the problem of the display difference between the first active area 120 and the second active area 130, effectively improve the defect of uneven display in the first active area 120 and the second active area 130, and enhance the display image quality. That is, the plurality of compensation wirings 150 are arranged at the corresponding positions of the second active area 130, so that the coupling environment of the second active area 130 and the coupling environment of the first active area 120 are the same or similar, which may solve the problem of Hole Mura in related art. Therefore, there are no strict restrictions on other attributes of the compensation wirings 150, such as the length of each compensation wiring 150, the spacing between the compensation wirings 150, and the level setting of compensation wirings 150.

Furthermore, the lengths of the plurality of compensation wirings 150 along the first direction X may be as shown in FIG. 5A and FIG. 5B. The lengths of the compensation wirings 150 in the first direction X are the same, that is, in some embodiments, the lengths of the plurality of compensation wirings 150 in the first direction X are the same.

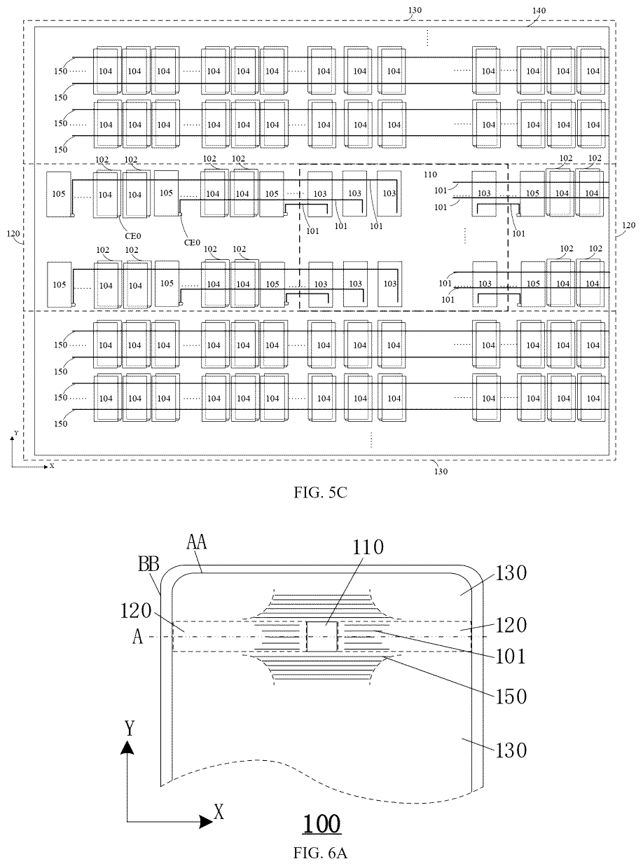

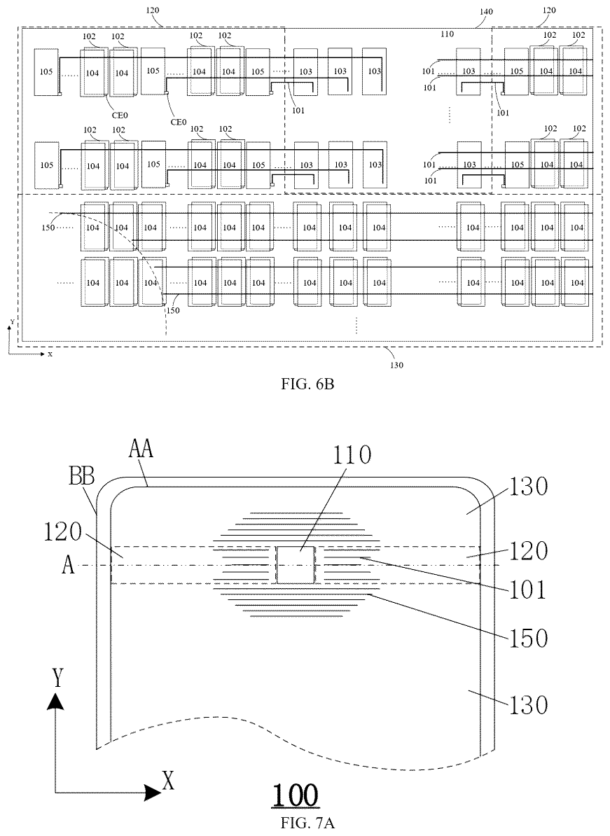

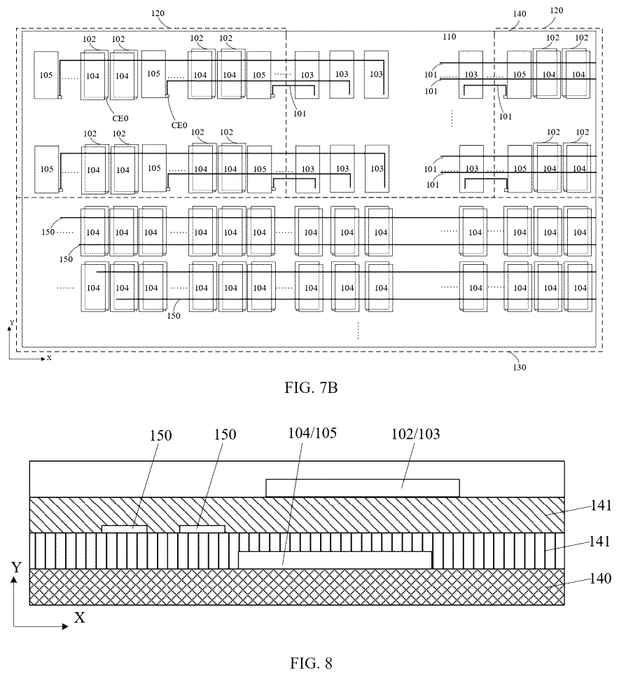

However, in some other embodiments, as shown in FIG. 6A and FIG. 7A, the lengths of the plurality of compensation wirings 150 in the first direction X decreases sequentially along the second direction Y away from the light-transmitting active area 110, i.e., the greater the distance between the compensation wiring 150 and the light-transmitting active area 110, the shorter the length of the compensation wiring 150. In this embodiment, by setting the length of compensation wiring 150 to a gradually shorter form, the coupling amount may be gradually reduced, which may effectively smooth the boundary of coupling and play a smooth transition role in the significant display difference between the first active area 120 and the second active area 130, thus improving the display effect of the second active area 130. As shown in FIG. 6B and FIG. 7B, they are schematic diagrams of the compensation wirings 150 overlapping with the first pixel circuits 104 located in the second active area 130. In some embodiments, the lengths of the plurality of compensation wirings 150 in the first direction X gradually decreases along the second direction Y away from the light-transmitting active area 110.

Among them, in different embodiments, the degree of shortening of each compensation wiring 150 may be specifically set according to the specific application scenario, as shown in FIG. 6A and FIG. 6B. The degree of shortening of each compensation wiring 150 may conform to a certain exponential function or any other variation law. In order to make the smoothing effect of the coupling boundary more obvious, as shown in FIG. 7A and FIG. 7B, the plurality of compensation wirings 150 may be made to decrease in length in a trapezoidal form, that is, the degree of length decrease between adjacent compensation wirings 150 is the same. That is, in some embodiments, the length difference between adjacent compensation wirings 150 among the plurality of compensation wirings 150 is equal.

In some embodiments, as shown in FIG. 8, the display panel 100 further includes at least one flat layer (PLN layer, Planarization) 141 located on a side of the plurality of first pixel circuits 104 and the plurality of second pixel circuits 105 away from the substrate 140; the plurality of compensation wirings 150 located on a side of the at least one flat layer 141 away from the substrate 140; and the plurality of first light-emitting elements 102 and the plurality of second light-emitting elements 103 located on a side of the plurality of compensation wirings 150 away from the substrate 140.

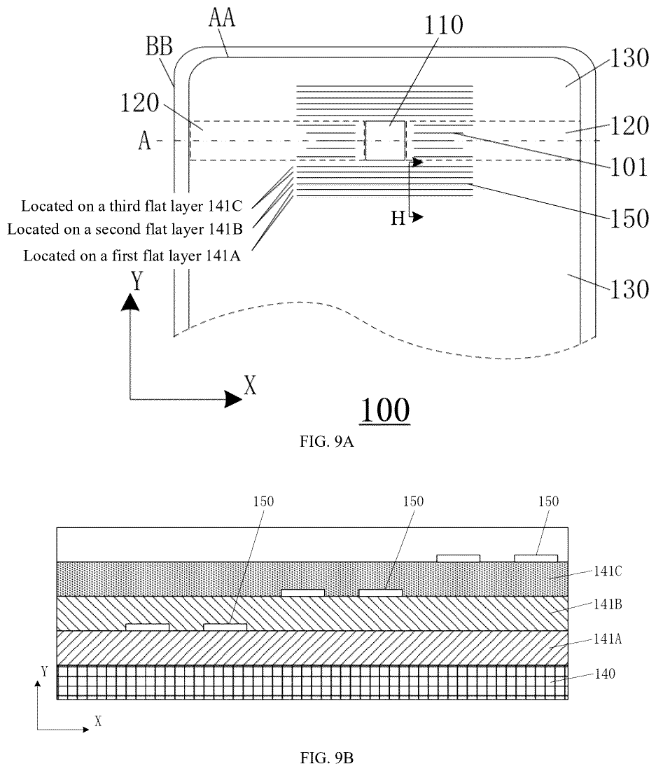

In some embodiments, the compensation wirings 150 may be arranged only on the same flat layer 141, which may solve the problem of significant display differences between the first active area 120 and the second active area 130, improve the defect of uneven display between the first active area 120 and the second active area 130, and enhance the display image quality. However, with this arrangement, there may be more obvious coupling boundaries in the second active area 130, thus in some embodiments, these coupling boundaries may be further smoothed and/or blurred. For example, the compensation wirings 150 may be arranged on different flat layers 141 to create a gradient change in the coupling effect, thereby performing smooth transition treatment on the coupling boundary. As shown in FIG. 9A and FIG. 9B, the at least one flat layer 141 includes three flat layers, the three flat layers including a first flat layer 141A, a second flat layer 141B and a third flat layer 141C. The first flat layer 141A, the second flat layer 141B and the third flat layer 141C are arranged in stacked along a direction away from the substrate 140; and the plurality of compensation wirings 150 are located on a side of the first flat layer 141A away from the substrate 140, located on a side of the second flat layer 141B away from the substrate 140, and located on a side of the third flat layer 141C away from the substrate 140, respectively.

As shown in FIG. 9A and FIG. 9B, in some embodiments, shortest distances from an orthographic projection of a compensation wiring 150 located on the side of the first flat layer 141A away from the substrate 140 on the substrate 140, an orthographic projection of a compensation wiring 150 located on the side of the second flat layer 141B away from the substrate 140 on the substrate 140, and an orthographic projection of a compensation wiring 150 located on the side of the third flat layer 141C away from the substrate 140 on the substrate 140 to the light-transmitting active area 110 decrease sequentially; or, the shortest distances from the orthographic projection of the compensation wiring 150 located on the side of the first flat layer 141A away from the substrate 140 on the substrate 140, the orthographic projection of the compensation wiring 150 located on the side of the second flat layer 141B away from the substrate 140 on the substrate 140, and the orthographic projection of the compensation wiring 150 located on the side of the third flat layer 141C away from the substrate 140 on the substrate 140 to the light-transmitting active area 110 increase sequentially.

The quantity of the compensation wirings 150 on each flat layer 141 may be adjusted according to specific application scenarios. For example, the quantities of the compensation wirings 150 arranged on different flat layers 141 are different, the flat layer 141 with a larger space is provided with more compensation wirings 150, and the flat layers 141 with a smaller space is provided with fewer compensation wirings 150. The quantity of the compensation wirings 150 on each flat layer 141 may also be set to be the same. That is, in some embodiments, the quantity of the compensation wirings 150 located on the side of the first flat layer 141A away from the substrate 140, the quantity of the compensation wirings 150 located on the side of the second flat layer 141B away from the substrate 140, and the quantity of the compensation wirings 150 located on the side of the third flat layer 141C away from the substrate 140 are equal.

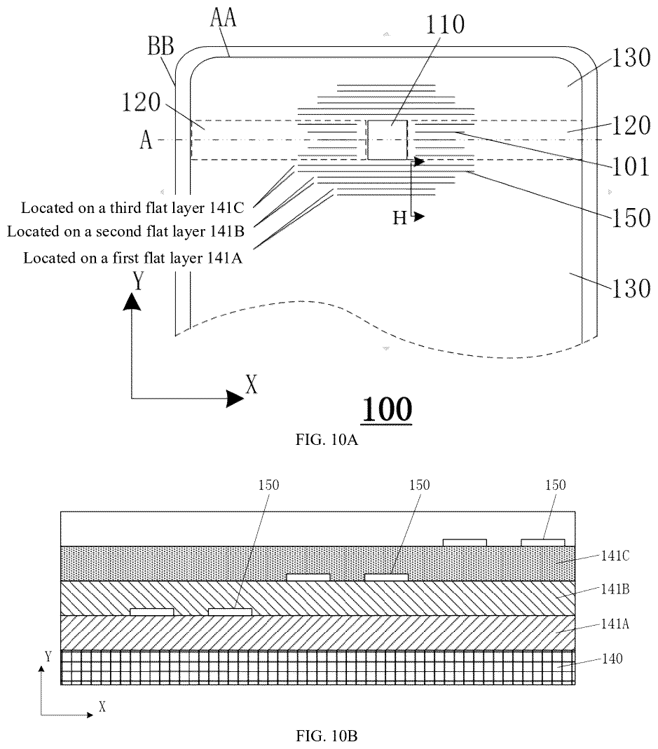

In some embodiments, based on the effect of smoothing the coupling boundary caused by the length variation of the compensation wirings 150 mentioned above, a unified length variation may be carried out in the form of dividing the compensation wirings 150 on the same flat layer 141 as one group, to achieve the effect of smoothing the coupling boundary. That is, in some embodiments, as shown in FIG. 10A and FIG. 10B, lengths, in the first direction X, of compensation wirings 150 arranged on a side of a same flat layer 141 away from the substrate 140 are equal; and lengths, in the first direction X, of compensation wirings 150 arranged on sides of different flat layers 141 away from the substrate 140 decrease sequentially along the second direction Y away from the light-transmitting active area 110.

Among them, since there may be a plurality of compensation wirings 150 on the same flat layer 141, the length of the compensation wirings 150 on this flat layer 141 is determined based on the distance from the compensation wiring 150 closest to the light-transmitting active area 110 on each layer to the light-transmitting active area 110. The greater the minimum distance, the shorter the length of the compensation wiring 150 on the flat layer 141. The length variation pattern between the compensating wirings 150 on each layer is the same as or similar to the length variation pattern of each compensating wiring 150 in the previous embodiment, and will not be repeated here. Among them, since the coupling boundary gradually expands outward with the increase of the quantity of the compensation wirings 150, if the compensation wirings 150 that are farther away are arranged on the lower flat layer 141 and the compensation wirings 150 that are closer are arranged on the upper flat layer 141 during the allocation of the flat layers, this may better gradually reduce the coupling amount between the compensation wirings 150 and the first pixel circuits 104 and/or the second pixel circuits 105, and show a gradient change, ultimately making the display difference between the first active area 120 and the second active area 130 smoothly transition, further improving the display image quality.

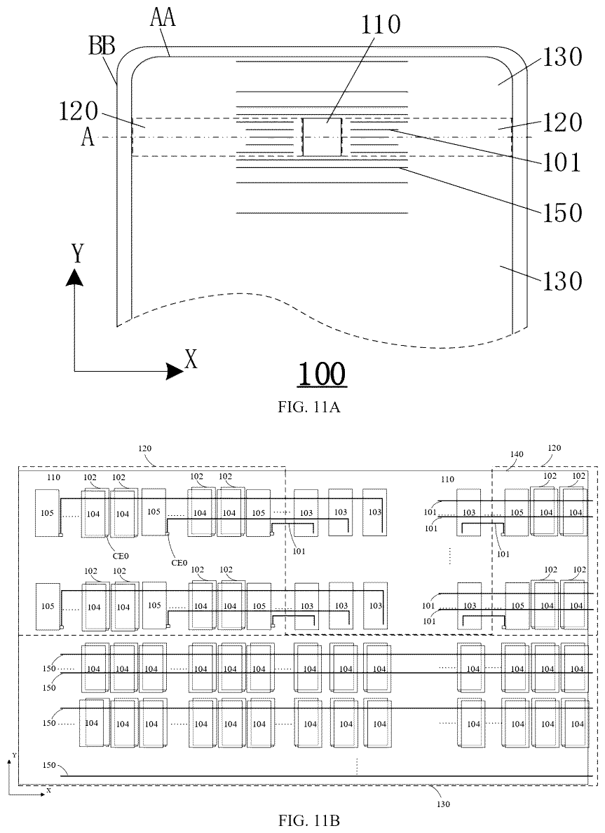

In some embodiments, the spacings between the plurality of compensation wirings 150 may be specifically set according to specific application scenarios. For example, as shown in FIG. 11A and FIG. 11B, in some embodiments, the spacing between the compensation wirings 150 close to the light-transmitting active area 110 may be set smaller, while the spacing between the compensation wirings 150 away from the light-transmitting active area 110 may be set larger. That is, the closer the compensation wirings 150 are to the light-transmitting active area 110, the denser compensation wirings 150 become, and the farther away the compensation wirings 150 are from the light-transmitting active area 110, the sparser the compensation wirings 150 become. This may be increased proportionally or exponentially. That is, in some embodiments, the spacing between two adjacent compensation wirings 150 in the plurality of compensation wirings 150 gradually increases along the second direction Y away from the light-transmitting active area 110. Certainly, in some embodiments, the spacing between any two adjacent compensation wirings 150 may also be the same.

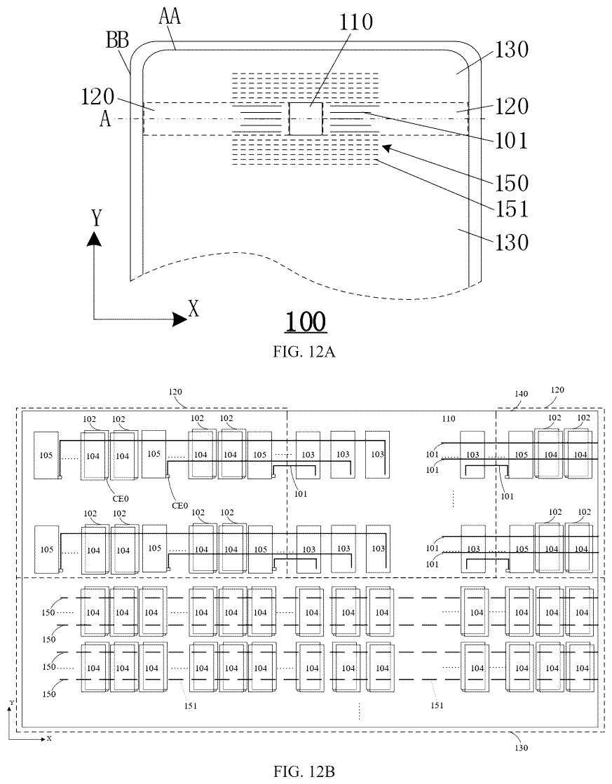

In some embodiments, according to the above, the coupling boundaries will be generated during coupling, which will affect the second active area 130 located in the second direction Y of the light-transmitting active area 110. Therefore, in addition to smoothing the coupling boundaries, it may also consider blurring the coupling boundaries. The processing method may be as shown in FIG. 12A and FIG. 12B, where each compensation wiring 150 is changed from an entire long wiring to shorter line segment wirings 151. By breaking the linear coupling phenomenon, the coupling boundary between the first active area 120 and the second active area 130 is blurred, further improving the display image quality. At the same time, it may be further limited that the spacing between any two adjacent line segment wirings 151 divided from the same compensation wiring 150 is the same. That is, in some embodiments, each of the plurality of compensation wirings 150 includes a plurality of line segment wirings 151, and the spacing between any two adjacent line segment wirings 151 in the same compensation wiring 150 is the same. Among them, the compensation wiring 150 may be divided into the line segment wirings 151 according to preset rules. The preset rules may be to specify the length of each line segment wiring 151 for segmentation, to determine how many segments to divide the compensation wirings 150 into for segmentation, or avoid certain structures according to the settings of the display panel 100 for segmentation. Certainly, in some embodiments, the spacing between adjacent line segment wirings 151 may also vary depending on the actual situations.

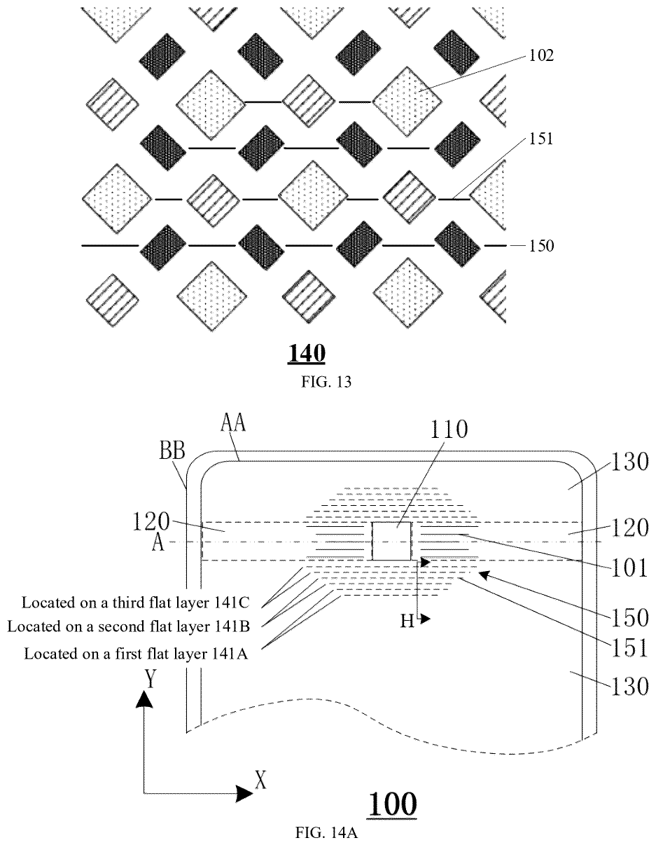

In some embodiments, the first light-emitting elements 102 and the second light-emitting elements 103 are usually arranged at an interval, with gaps between each row or each column of light-emitting elements. Furthermore, the compensation wiring 150 and the line segment wirings 151 formed by dividing the compensation wiring 150 may be arranged in these gaps to prevent the increase in process and production costs caused by vertically setting over multiple layers of structures at the same position, as well as possible mutual influence. Therefore, in some embodiments, as shown in FIG. 13, the compensation wirings 150 may be arranged at the gap positions between the first light-emitting elements 102 within the second active area 130 where the compensation wirings 150 are located. In some specific embodiments, as shown in FIG. 13, one compensation line 150 may be arranged in the gap between two adjacent rows of first light-emitting elements 102. If the compensation wiring 150 is divided into the line segment wirings 151, each line segment wiring 151 may be arranged between two adjacent columns of first light-emitting elements 102. That is, in some embodiments, the orthographic projections of the plurality of compensation wirings 150 on the substrate 140 are located between the orthographic projections of the plurality of first light-emitting elements 102 on the substrate 140; or the orthographic projections of the plurality of compensation wirings 150 on the substrate 140 overlap with the orthographic projections of the plurality of first light-emitting elements 102 on the substrate 140.

In some embodiments, in order to solve the problem of the display difference between the first active area 120 and the second active area 130, and to make the coupling effect between the compensation wirings 150 and the first pixel circuits 104 and/or the second pixel circuits 105 closer to the coupling effect between the conductive wires 101 and the first pixel circuits 104 and/or the second pixel circuits 105, as shown in FIG. 5A to FIG. 5C, the plurality of compensation wirings 150 are arranged in parallel in the first direction X. That is, the plurality of compensation wirings 150 and the conductive wires 101 are parallel to each other.

In some embodiments, since the compensation wirings 150 are a structure applied to the display panel 100, in order not to affect the display effect and achieve good coupling effect, the compensation wirings 150 are specifically made of transparent indium tin oxide (ITO). In the specific design of the display panel 100, it may be a dummy ITO wiring (Dummy ITO wiring), that is, the dummy ITO wiring is not connected to any potential, or the compensation wirings 150 are connected to a constant voltage potential.

In some embodiments, since the light-transmitting active area 110 may be located in the middle of the active area AA, the upper, lower, left, and right sides of the light-transmitting active area 110 are surrounded by the active area AA. Furthermore, in some embodiments, as shown in FIG. 5B and FIG. 5C, the first active area 120 is located on two sides of the light-transmitting active area 110 along the first direction X, and the second active area 130 is located on two sides of the light-transmitting active area 110 along the second direction Y; and the plurality of compensation wirings 150 are located in the second active area 130 on the two sides of the light-transmitting active area 110. In order to improve the smoothness and blurring effect of the coupling boundaries, similar to the previous embodiments, as shown in FIG. 7A and FIG. 7B, lengths, in the first direction X, of compensation wirings 150 in the second active area 130 located on any one side of the light-transmitting active area 110 decrease sequentially along the second direction Y away from the light-transmitting active area 110.

While in some other embodiments, the compensation wirings 150 on the two sides may be symmetrically arranged with the central axis A of the light-transmitting active area 110 as the symmetrical axis. That is, in some embodiments, as shown in FIG. 5B, the light-transmitting active area 110 has a symmetrical axis A along the first direction X, the plurality of compensation wirings 150 respectively located on the two sides of the light-transmitting active area 110 along the second direction Y are symmetrically arranged with respect to the symmetrical axis A. Among them, the central axis A is a central axis of the light-transmitting active area 110 in the first direction X. In some embodiments, since the light-transmitting active area 110 may have a relatively regular shape, such as a circle or square, the central axis A may be determined based on the related parameters of the specific light-transmitting active area 110.

In some embodiments, as shown in FIG. 5A to FIG. 12B, the plurality of conductive wires 101 are located in the first active area 120 on the two sides of the light-transmitting active area 110.

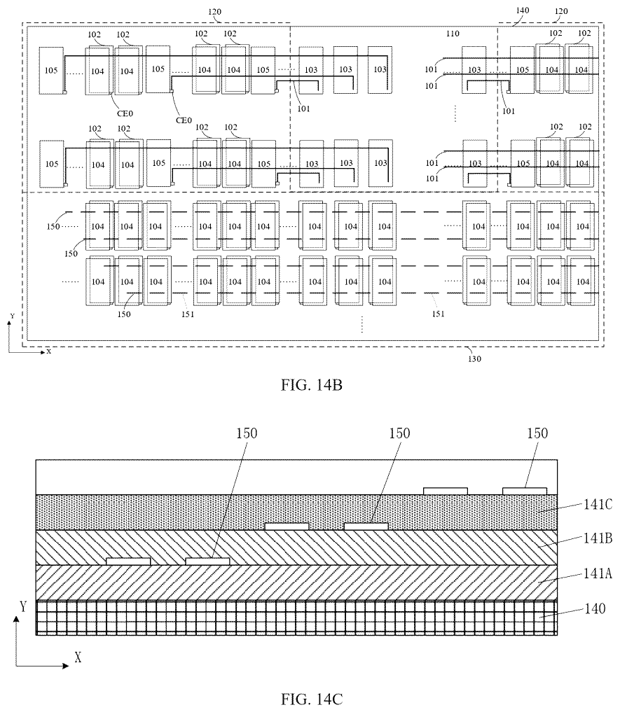

According to the aforementioned embodiments, the compensation wirings 150 have been explained from different perspectives. Furthermore, in specific implementation, combinations between different embodiments may be made according to specific scene requirements and effect requirements. For example, in a specific embodiment, as shown in FIG. 14A to FIG. 14C, the compensation wirings 150 are designed as symmetrical trapezoidal wiring structures on the two sides of the light-transmitting active area 110. Among them, as shown in FIG. 14C, two longest compensation wirings 150 closest to the first active area 120 on the same side are located on the third flat layer 141C (such as a PLN4 layer); two shorter compensation wirings 150 are arranged on the second flat layer 141B (such as a PLN3 layer) below the third flat layer 141C; and two shortest compensation wirings 150 are arranged on the bottommost first flat layer 141A (such as a PLN2 layer). As shown in FIG. 14A or FIG. 14B, the compensation wirings 150 on the same side become shorter as the distance from the light-transmitting active area 110 in the second direction Y increases, and the spacing between adjacent compensation wirings 150 on the same side is the same. Moreover, each compensation wiring 150 is divided into a plurality of line segment wirings 151, and the line segment wirings 151 of the same compensation wiring 150 are arranged to avoid the first light-emitting elements 102 in the same row. Finally, in the specific implementation, the compensation wiring 150 closest to the first active area 120 is the longest, and then gradually decreases (i.e. the compensation wiring 150 becomes shorter as it is farther away), so that the coupling amount between the compensation wirings 150 and the first pixel circuits 104 and/or the second pixel circuits 105 gradually decreases and shows a gradient change, ultimately making the display difference between the first active area 120 and the second active area 130 smoothly transition, further improving the display image quality. And by using the short-range line segment wirings 151 to break the linear coupling phenomenon, the coupling boundaries between the first active area 120 and the second active area 130 is blurred, further improving the display image quality.

Below is an exemplary explanation of the pixel circuits and film structures of the active area of the display panel 100.

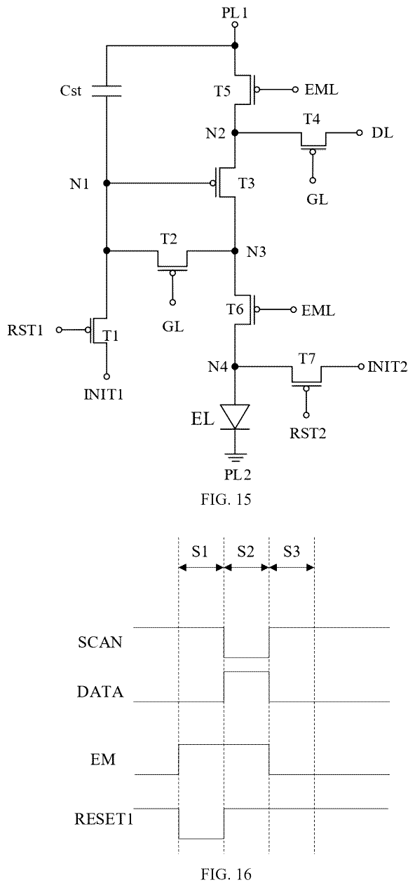

FIG. 15 is an equivalent circuit diagram of the pixel circuits according to the embodiments of the present application. FIG. 16 is a schematic diagram of the working timing of the pixel circuits provided in FIG. 15. The pixel circuit of this exemplary embodiment is illustrated taking a 7T1C (i.e., 7 transistors and 1 capacitor) structure as an example. However, this embodiment is not limited to this. For example, the pixel circuit may also be a 3T1C (i.e., 3 transistors and 1 capacitor) structure, a 5T1C (i.e., 5 transistors and 1 capacitor) structure, an 8T1C (i.e., 8 transistors and 1 capacitor) structure, or an 8T2C (i.e., 8 transistors and 2 capacitors) structure.

In some exemplary implementations, as shown in FIG. 15, the pixel circuit of this example may include six switching transistors (T1, T2, T4 to T7), one driving transistor T3, and one storage capacitor Cst. The six switching transistors are a data writing transistor T4, a threshold compensation transistor T2, a first light-emitting control transistor T5, a second light-emitting control transistor T6, a first reset transistor T1, and a second reset transistor T7. The light-emitting element EL may include an anode, a cathode, and an organic luminescent layer disposed between the anode and cathode.

In some exemplary implementations, the driving transistor and the six switching transistors may be P-type transistors or may be N-type transistors. Using the same type of transistors in the pixel circuit may simplify the process flow, reduce the process difficulty of the substrate, and improve the product yield. In some possible implementations, the driving transistor and the six switching transistors may include the P-type transistors and the N-type transistors.

In some exemplary implementations, the driving transistor and the six switching transistors may use low-temperature poly-silicon thin film transistors, or may use oxide thin film transistors, or may use the low-temperature poly-silicon thin film transistors and the oxide thin film transistors. The active layer of the low-temperature poly-silicon thin film transistors uses low temperature poly-silicon (LTPS), while the active layer of the oxide thin film transistors uses oxide semiconductors (Oxide). The low-temperature poly-silicon thin film transistors have advantages such as high mobility and fast charging, while the oxide thin film transistors have advantages such as low leakage current. Integrating the low-temperature poly-silicon thin film transistors and the oxide thin film transistors on one substrate to form a low-temperature polycrystalline oxide (LTPO) substrate may utilize the advantages of both, achieve low-frequency driving, reduce power consumption, and improve display quality.

In some exemplary implementations, as shown in FIG. 15, the substrate may include scanning lines GL, a data line DL, a first power line PL1, a second power line PL2, light-emitting control lines EML, a first initial signal line INIT1, a second initial signal line INIT2, a first reset control line RST1, and a second reset control line RST2. In some examples, the first power line PL1 may be configured to provide a constant first voltage signal VDD to the pixel circuit, and the second power line PL2 may be configured to provide a constant second voltage signal VSS to the pixel circuit, with the first voltage signal VDD being greater than the second voltage signal VSS. The scanning lines GL may be configured to provide scanning signals SCAN to the pixel circuit, the data line DL may be configured to provide a data signal DATA to the pixel circuit, the light-emitting control lines EML may be configured to provide light-emitting control signals EM to the pixel circuit, the first reset control line RST1 may be configured to provide a first reset control signal RESET1 to the pixel circuit, and the second reset control line RST2 may be configured to provide a second reset control signal RESET2 to the pixel circuit. In some examples, in the pixel circuit at the nth row, the first reset control line RST1 may be electrically connected to the scanning line GL of the pixel circuit at the (n−1) th row, to be input with the scanning signal SCAN (n−1), i.e., the first reset control signal RESET1 (n) is the same as the scanning signal SCAN (n−1). The second reset control line RST2 may be electrically connected to the scanning line GL of the pixel circuit at the nth row to be input with the scanning signal SCAN (n), that is, the second reset control signal RESET2 (n) is the same as the scanning signal SCAN (n). In some examples, the second reset control line RST2 electrically connected to the pixel circuit at the nth row and the first reset control line RST1 electrically connected to the pixel circuit at the (n+1) th row may be an integrated structure. Among them, n is an integer greater than 0. In this way, the signal lines on the substrate may be reduced, achieving a narrow frame design for the substrate. However, this embodiment is not limited to this.

In some exemplary implementations, the first initial signal line INIT1 may be configured to provide a first initial signal to the pixel circuit, and the second initial signal line INIT2 may be configured to provide a second initial signal to the pixel circuit. For example, the first initial signal may be different from the second initial signal. The first initial signal and the second initial signal may be constant voltage signals, and their magnitude may be between the first voltage signal VDD and the second voltage signal VSS, but is not limited to this. In other examples, the first initial signal and the second initial signal may be the same, and only the first initial signal line may be set to provide the first initial signal.

In some exemplary implementations, as shown in FIG. 15, the driving transistor T3 is electrically connected to the light-emitting element EL and outputs a driving current to drive the light-emitting element EL to emit light under the control of signals such as the scanning signal SCAN, the data signal DATA, the first voltage signal VDD, and the second voltage signal VSS. A gate of the data writing transistor T4 is electrically connected to the scanning line GL, a first electrode of the data writing transistor T4 is electrically connected to the data line DL, and a second electrode of the data writing transistor T4 is electrically connected to the first electrode of the driving transistor T3. A gate of the threshold compensation transistor T2 is electrically connected to the scanning line GL, a first electrode of the threshold compensation transistor T2 is electrically connected to a gate of the driving transistor T3, and a second electrode of the threshold compensation transistor T2 is electrically connected to a second electrode of the driving transistor T3. A gate of the first light-emitting control transistor T5 is electrically connected to the light-emitting control line EML, a first electrode of the first light-emitting control transistor T5 is electrically connected to the first power line PL1, and a second electrode of the first light-emitting control transistor T5 is electrically connected to the first electrode of the driving transistor T3. The gate of the second light-emitting control transistor T6 is electrically connected to the light-emitting control line EML, a first electrode of the second light-emitting control transistor T6 is electrically connected to the second electrode of the driving transistor T3, and a second electrode of the second light-emitting control transistor T6 is electrically connected to the anode of the light-emitting element EL. The first reset transistor T1 is electrically connected to the gate of the driving transistor T3 and configured to reset the gate of the driving transistor T3. The second reset transistor T7 is electrically connected to the anode of the light-emitting element EL and configured to reset the anode of the light-emitting element EL. A gate of the first reset transistor T1 is electrically connected to the first reset control line RST1, a first electrode of the first reset transistor T1 is electrically connected to the first initial signal line INIT1, and a second electrode of the first reset transistor T1 is electrically connected to the gate of the driving transistor T3. A gate of the second reset transistor T7 is electrically connected to the second reset control line RST2, a first electrode of the second reset transistor T7 is electrically connected to the second initial signal line INIT2, and the second electrode of the second reset transistor T7 is electrically connected to the anode of the light-emitting element EL. A first capacitor plate of the storage capacitor Cst is electrically connected to the gate of the driving transistor T3, and a second capacitor plate of the storage capacitor Cst is electrically connected to the first power line PL1.

In this example, a first node N1 is a connection point of the storage capacitor Cst, the first reset transistor T1, the driving transistor T3, and the threshold compensation transistor T2. A second node N2 is a connection point of the first light-emitting control transistor T5, the data writing transistor T4, and the driving transistor T3. A third node N3 is a connection point of the driving transistor T3, the threshold compensation transistor T2, and the second light-emitting control transistor T6. A fourth node N4 is a connection point of the second light-emitting control transistor T6, the second reset transistor T7, and the light-emitting element EL.

The working process of the pixel circuit illustrated in FIG. 15 will be described below with reference to FIG. 16. Taking the plurality of transistors included in the pixel circuit shown in FIG. 14 all being the P-type transistors as an example for explanation.

In some exemplary implementations, as shown in FIG. 16, within one frame of the

display time period, the working process of the pixel circuit may include: a first stage S1, a second stage S2, and a third stage S3.

The first stage S1 is called a reset stage. The first reset control signal RESET1 provided by the first reset control line RST1 is a low-level signal, causing the first reset transistor TI to conduct. The first initial signal provided by the first initial signal line INIT1 is provided to the first node N1, initializing the first node N1 and clearing the original data voltage in the storage capacitor Cst. The scanning signal SCAN provided by the scanning line GL is a high-level signal, and the light-emitting control signal EM provided by the light-emitting control line EML is a high-level signal, causing the data writing transistor T4, the threshold compensation transistor T2, the first light-emitting control transistor T5, the second light-emitting control transistor T6, and the second reset transistor T7 to be turned off. At this stage, the light-emitting element EL does not emit light.

The second stage S2 is called a data writing stage or a threshold compensation stage. The scanning signal SCAN provided by the scanning line GL is a low-level signal, the first reset control signal RESET1 provided by the first reset control line RST1 and the light-emitting control signal EM provided by the light-emitting control line EML are both high-level signals, and the data line DL outputs a data signal DATA. At this stage, due to the low level of the first capacitor plate of the storage capacitor Cst, the driving transistor T3 is turned on. The scanning signal SCAN is a low-level signal, causing the threshold compensation transistor T2, the data writing transistor T4, and the second reset transistor T7 to conduct. The threshold compensation transistor T2 and the data writing transistor T4 are turned on, so that the data voltage Vdata output from the data line DL is provided to the first node N1 passing through the second node N2, the conducting driving transistor T3, the third node N3, and the conducting threshold compensation transistor T2. The difference between the data voltage Vdata output from the data line DL and the threshold voltage of the driving transistor T3 is charged into the storage capacitor Cst. The voltage of the first capacitor plate (i.e., the first node N1) of the storage capacitor Cst is Vdata-|Vth|, among them, Vdata is the data voltage output from the data line DL and Vth is the threshold voltage of the driving transistor T3. The second reset transistor T7 is turned on, so that the second initial signal provided by the second initial signal line INIT2 is provided to the anode of the light-emitting element EL, initializing (resetting) the anode of the light-emitting element EL, clearing its internal pre-stored voltage, completing initialization, and ensuring that the light-emitting element EL does not emit light. The first reset control signal RESET1 provided by the first reset control line RST1 is a high-level signal, causing the first reset transistor T1 to be turned off. The light-emitting control signal EM provided by the light-emitting control signal line EML is a high-level signal, causing the first light-emitting control transistor T5 and the second light-emitting control transistor T6 to be turned off.

The third stage S3 is called a luminescent stage. The light-emitting control signal EM provided by the light-emitting control signal line EML is a low-level signal, while the scanning signal SCAN provided by the scanning line GL and the first reset control signal RESET1 provided by the first reset control line RST1 are high-level signals. The light-emitting control signal EM provided by the light-emitting control signal line EML is a low-level signal, causing the first light-emitting control transistor T5 and the second light-emitting control transistor T6 to conduct. The first voltage signal VDD output from the first power line PL1 provides a driving voltage to the anode of the light-emitting element EL passing through the conducting first light-emitting control transistor T5, the driving transistor T3, and the second light-emitting control transistor T6, to drive the light-emitting element EL to emit light.

In the driving process of the pixel circuit, the driving current flowing through the driving transistor T3 is determined by the voltage difference between the gate and the first electrode of the driving transistor T3. Due to the voltage of the first node N1 being Vdata-|Vth|, the driving current of the driving transistor T3 is:

I=K×(Vgs−Vth)2=K×[(VDD−Vdata+|Vth|)−Vth]2=K×[VDD−Vdata]2.

Among them, I is the driving current flowing through the driving transistor T3, that is, the driving current driving the light-emitting element EL, K is a constant, Vgs is the voltage difference between the gate and the first electrode of the driving transistor T3, Vth is the threshold voltage of the driving transistor T3, Vdata is the data voltage output from the data line DL, and VDD is the first voltage signal output from the first power line PL1.

From the above equation, it can be seen that the current flowing through the light-emitting element EL is independent of the threshold voltage of the driving transistor T3. Therefore, the pixel circuit of this embodiment may effectively compensate for the threshold voltage of the driving transistor T3.

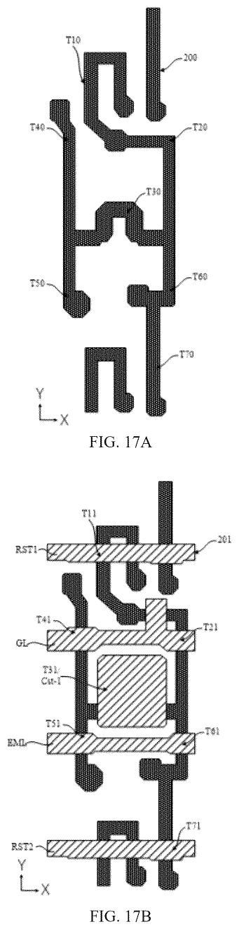

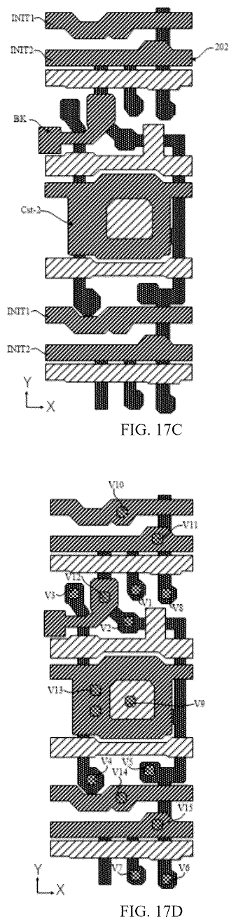

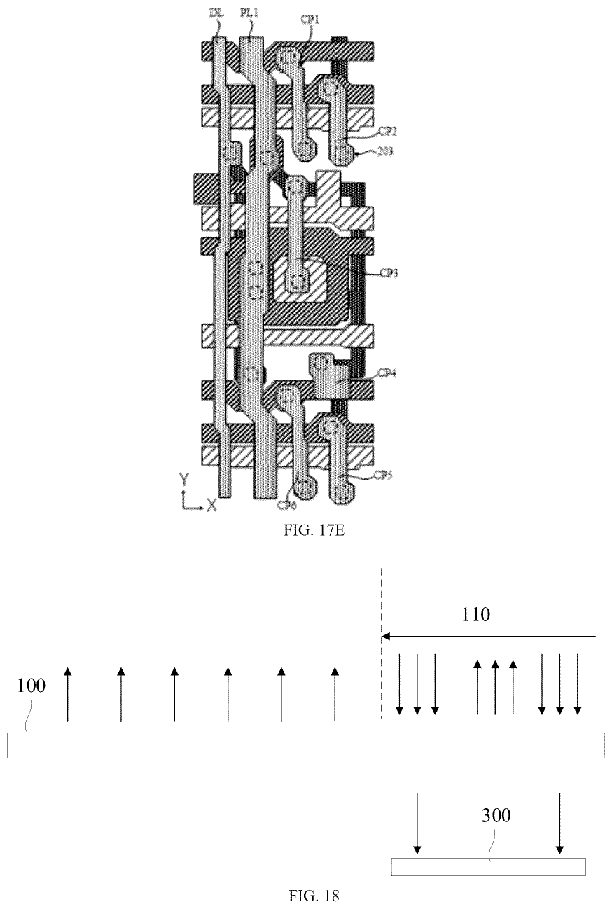

FIG. 17A to FIG. 17E are schematic diagrams of top view structures of the circuit structure layers of the under-screen camera area 111 according to an embodiment of the present application. FIG. 17A is a schematic diagram of a top view structure of a display panel after formation of a semiconductor layer. FIG. 17B is a schematic diagram of a top view structure of a display panel after formation of a first gate metal layer. FIG. 17C is a schematic diagram of a top view structure of a display panel after formation of a second gate metal layer. FIG. 17D is a schematic diagram of a top view structure of a display panel after formation of a third insulation layer. FIG. 17E is a schematic diagram of a top view structure of a display panel after formation of a first source-drain metal layer.

In some exemplary implementations, the preparation process of the display panel may include the following operations. Taking one pixel circuit as an example for illustration. The circuit structure of the pixel circuit may be shown in FIG. 14.
(1) Providing the substrate 140.

In some exemplary implementations, the substrate 140 may be a rigid substrate, such as a glass substrate. However, this embodiment is not limited to this. For example, the substrate 140 may be a flexible substrate.
(2) Forming the semiconductor layer 200.

In some exemplary implementations, a semiconductor thin film is deposited on the substrate 140 and patterned through a patterning process, to form the semiconductor layer 200. As shown in FIG. 17A, the semiconductor layer 200 may include active layers of a plurality of transistors of the pixel circuit (for example, including: an active layer T10 of the first reset transistor T1, an active layer T20 of the threshold compensation transistor T2, an active layer T30 of the driving transistor T3, an active layer T40 of the data writing transistor T4, an active layer T50 of the first light-emitting control transistor T5, an active layer T60 of the second light-emitting control transistor T6, and an active layer T70 of the second reset transistor T7). The active layers of the seven transistors in one pixel circuit may be connected to each other to form an integrated structure.

In some exemplary implementations, the material of the semiconductor layer 200 may include, for example, polycrystalline silicon. The active layer may include at least one channel region and a plurality of doped regions. The channel region may be undoped with impurities and possess semiconductor properties. The plurality of doped regions may be located on two sides of the channel region and doped with the impurities, thus possessing conductivity. The impurities may vary depending on the types of the transistors. In some examples, the doped region of the active layer may be interpreted as the source electrode or the drain electrode of the transistor. The part of the active layer between the transistors may be interpreted as wirings doped with the impurities, which may be used to electrically connect the transistors.
(3) Forming the first gate metal layer.

In some exemplary implementations, a first insulation film and a first metal film are sequentially deposited on the substrate 140 forming the aforementioned structure, and the first metal film is patterned through a patterning process to form a first insulation layer covering the semiconductor layer 200 and a first gate metal layer 201 disposed on the first insulation layer. As shown in FIG. 17B, the first gate metal layer 201 may include: the gates of the plurality of transistors of the pixel circuit, as well as the first capacitor plate Cst-1 of the storage capacitor Cst, the first reset control line RST1, the second reset control line RST2, the scanning line GL, and the light-emitting control line EML. The first reset control line RST1 and the gate T11 of the first reset transistor T1 may be an integrated structure. The scanning line GL and the gate T41 of the data writing transistor T4 and the gate T21 of the threshold compensation transistor T2 may be an integrated structure. The gate T31 of the driving transistor T3 and the first capacitor plate Cst-1 of the storage capacitor Cst may be an integrated structure. The light-emitting control line EML, the gate T51 of the first light-emitting control transistor T5, and the gate T61 of the second light-emitting control transistor T61 may be an integrated structure. The second reset control line RST2 and the gate T71 of the second reset transistor T7 may be an integrated structure.
(4) Forming a second gate metal layer.

In some exemplary implementations, a second insulation film and a second metal film are sequentially deposited on the substrate 140 forming the aforementioned structure, and the second metal film is patterned through a patterning process to form a second insulation layer covering the first gate metal layer 201 and a second gate metal layer 202 disposed on the second insulation layer. As shown in FIG. 17C, the second gate metal layer 202 may include: the second capacitor plate Cst-2 of the storage capacitor Cst of the pixel circuit, a shielding electrode BK, the first initial signal line INIT1, and the second initial signal line INIT2. The shielding electrode BK may be configured to shield the impact of the data voltage jump on key nodes, thus avoiding the potential of the key nodes in the pixel circuit affected by the data voltage jump and improving display effect.
(5) Forming a third insulation layer and a first source-drain metal layer.

In some exemplary implementations, a third insulation film is deposited on the substrate 140 forming the aforementioned structure, and a third insulation layer is formed through a patterning process. The third insulation layer is provided with a plurality of pixel vias. Subsequently, a third metal thin film is deposited and patterned through a patterning process to form a first source-drain metal layer 203 located on the third insulation layer.

In some examples, as shown in FIG. 17D, the third insulation layer may be provided with the plurality of pixel vias, for example, may include the first pixel via V1 to the fifteenth pixel via V15. The third insulation layer, the second insulation layer, and the first insulation layer inside the first pixel via V1 to the eighth pixel via V8 are removed, to expose the surface of the semiconductor layer 200. The third insulation layer and the second insulation layer inside the ninth pixel via V9 are removed, to expose the surface of the first gate metal layer 201. The third insulation layer inside the tenth pixel via V10 to the fifteenth pixel via V15 is removed, to expose the surface of the second gate metal layer 202.

In some examples, as shown in FIG. 17E, the first source-drain metal layer 203 may include a data line DL, a first power line PL1, and a plurality of connection electrodes (e.g., the first connection electrode CP1 to the sixth connection electrode CP6). The first connection electrode CP1 may be electrically connected to the first doped region of the active layer T10 of the first reset transistor T1 through the first pixel via V1, and may also be electrically connected to the first initial signal line INIT1 through the tenth pixel via V10. The second connection electrode CP2 may be electrically connected to the first doped region of the active layer of the second reset transistor in the previous row of pixel circuits through the eighth pixel via V8, and may also be electrically connected to the second initial signal line INIT2 through the eleventh pixel via V11. The third connection electrode CP3 may be electrically connected to the gate T31 of the driving transistor T3 through the ninth pixel via V9, and may also be electrically connected to the first doped region of the active layer T20 of the threshold compensation transistor T2 through the second pixel via V2. The fourth connection electrode CP4 may be electrically connected to the second doped region of the active layer T60 of the second light-emitting control transistor T6 through the fifth pixel via V5. The fifth connection electrode CP5 may be electrically connected to the first doped region of the active layer T70 of the second reset transistor T7 through the sixth pixel via V6, and may also be electrically connected to another second initial signal line INIT2 through the fifteenth pixel via V15. The sixth connection electrode CP6 may be electrically connected to the first doped region of the active layer of the first reset transistor in the next row of pixel circuits through the seventh pixel via V7, and may also be electrically connected to another first initial signal line INIT1 through the fourteenth via V14. The data line DL may be electrically connected to the first doped region of the active layer T40 of the data writing transistor T4 through the third pixel via V3. The first power line PL1 may be electrically connected to the shielding electrode BK through the twelfth pixel via V12, may also be electrically connected to the first doped region of the active layer T50 of the first light-emitting control transistor T5 through the fourth pixel via V4, and may also be electrically connected to the second capacitor plate Cst-2 of the storage capacitor Cst through two thirteenth pixel via V13 arranged vertically.

In some exemplary implementations, a fourth insulation film is deposited on the substrate 140 forming the aforementioned structure, and a fourth insulation layer is formed through a patterning process. The fourth insulation layer is provided with multiple vias (such as the first via K1 and the second via K2) that expose the surface of the first source-drain metal layer 203.

Thus, the circuit structure layers of the first active area 120 and the second active area 130 have been prepared. The light-transmitting active area 110 may include a substrate 140 and a first insulation layer, a second insulation layer, a third insulation layer, and a fourth insulation layer that are stacked on the substrate 140.
(6) Forming multiple transparent conductive layers.

In some exemplary implementations, a first flat thin film is coated on the substrate 140 forming the aforementioned structure, and a first flat layer is formed through the patterning process. Subsequently, the first transparent conductive thin film is deposited and patterned through the patterning process to form a first transparent conductive layer arranged on the first flat layer. Subsequently, a second flat thin film is coated on the substrate 140 forming the aforementioned structure, and a second flat layer is formed through the patterning process. Subsequently, a second transparent conductive thin film is deposited and patterned through the patterning process to form a second transparent conductive layer arranged on the second flat layer. Subsequently, a third flat thin film is coated on the substrate 140 forming the aforementioned structure, and a third flat layer is formed through the patterning process. Subsequently, a third transparent conductive thin film is deposited and patterned through the patterning process to form a third transparent conductive layer arranged on the third flat layer. The first transparent conductive layer, the second transparent conductive layer, and the third transparent conductive layer may all include multiple transparent conductive wires. However, this embodiment does not limit the quantity of the transparent conductive layers.
(7) Forming a luminescent structure layer.

In some exemplary implementations, a fourth flat thin film is coated on the substrate 140 forming the aforementioned structure, and a fourth flat layer is formed through the patterning process. Subsequently, an anode conductive thin film is deposited and patterned through the patterning process to form an anode layer arranged on the fourth flat layer. Subsequently, a pixel definition thin film is coated on the substrate forming the aforementioned pattern, and a pixel define layer (PDL) is formed through masking, exposure, and development processes. The pixel define layer is formed with multiple pixel openings that expose the anode layer. An organic light-emitting layer is formed within the pixel opening formed earlier, and the organic light-emitting layer is connected to the anode. Subsequently, a cathode thin film is deposited and patterned through the patterning process to form a cathode pattern. The cathode is electrically connected to the organic light-emitting layer and the second power line, respectively. Subsequently, an encapsulation layer is formed on the cathode, the encapsulation layer may include a laminated structure of inorganic materials/organic materials/inorganic materials.

In some exemplary implementations, the first gate metal layer 201, the second gate metal layer 202, the first source-drain metal layer 203, the second source-drain metal layer, and the capacitor compensation layer may be made of metal materials, such as any one or more of silver (Ag), copper (Cu), aluminum (Al), and molybdenum (Mo), or alloy materials of the above metals, such as aluminum neodymium alloy (AlNd) or molybdenum niobium alloy (MoNb), which may be a single-layer structure or a multi-layer composite structure, such as Mo/Cu/Mo, etc. The first transparent conductive layer to the third transparent conductive layer may be made of transparent conductive materials, such as indium tin oxide (ITO). The first insulation layer, the second insulation layer, the third insulation layer, and the fourth insulation layer may use any one or more of silicon oxide (SiOx), silicon nitride (SiNx), and silicon oxynitride (SiON), and may be of a single layer, multiple layers, or a composite layer. The first flat layer to the fourth flat layer may be made of organic materials such as polyimide, acrylic, or polyethylene terephthalate. The pixel define layer may be made of organic materials such as polyimide, acrylic, or polyethylene terephthalate. The anode layer may be made of reflective materials such as metals, and the cathode may be made of transparent conductive materials. However, this embodiment is not limited to this.

The structure and preparation process of the display panel 100 in this embodiment are only illustrative. In some exemplary implementations, the corresponding structure may be changed and the composition process may be added or reduced according to actual needs. The preparation process of this exemplary embodiment may be achieved using currently mature preparation equipment, which may be well compatible with existing preparation processes. The process is simple and easy to implement, with high production efficiency, a low production cost, and a high yield rate.

Based on the same concept, the present application also provides a display device including the display panel 100 as described in any of the aforementioned embodiments.

FIG. 18 is a schematic structural diagram of the display device provided in the embodiments of the present application. As shown in FIG. 18, this embodiment provides a display device including: a sensor 300 located on a side of a non-display surface of the display panel 100, and an orthographic projection of the sensor 300 on the display panel 100 overlaps with an orthographic projection of the light-transmitting active area 110 of the display panel 100 on the display panel 100. Among them, the orthographic projection of the sensor 300 may be entirely located within the light-transmitting active area 110 of the display panel 100, or only partially overlapped. The sensor 300 may be a camera.

In some exemplary implementations, the display panel 100 may be a flexible OLED display panel, QLED display panel, Micro-LED display panel, or Mini-LED display panel, etc. The display device may be any product or component with the display function, such as an OLED display, a mobile phone, a tablet computer, a television, a monitor, a laptop, a digital photo frame, a navigation device, etc. The embodiments of the present application are not limited to this.

The display device of the above embodiments is used to apply the corresponding display panel in the above embodiments, and has the beneficial effects of the corresponding display panel embodiments, which will not be repeated here.

Persons skilled in the art should understand that the discussion of any of the above embodiments is only exemplary and is not intended to imply that the scope of the present application (including the claims) is limited to these examples. Under the concept of the present application, the technical features of the above embodiments or different embodiments may also be combined, and the steps may be implemented in any order. There are many other variations of the different aspects of the embodiments of the present application as described above, which are not provided in detail for the sake of simplicity.

In addition, to simplify the explanation and discussion, and to avoid making the embodiments of the present application difficult to understand, well-known power/ground connections to integrated circuit (IC) chips and other components may or may not be shown in the provided drawings. In addition, the device may be shown in the form of a block diagram to avoid making the embodiments of the present application difficult to understand, and this also takes into account the fact that the details of the implementation of these block diagram devices are highly dependent on the platform on which the embodiments of the present application will be implemented (i.e., these details should be fully within the understanding of those skilled in the art). In describing the exemplary embodiments of the present application with specific details (such as circuits), it is apparent to those skilled in the art that the embodiments of the present application may be implemented without these specific details or with changes in these specific details. Therefore, these descriptions should be considered illustrative rather than restrictive.

Although the present application has been described in conjunction with specific embodiments, many substitutions, modifications, and variations of these embodiments will be apparent to those skilled in the art based on the preceding description. For example, other memory architectures (such as dynamic RAM (DRAM)) may use the embodiments discussed.

The embodiments of the present application are intended to cover all such substitutions, modifications, and variations falling within the broad scope of the appended claims. Therefore, any omission, modification, equivalent substitution, improvement, etc. made within the spirit and principles of the embodiments of the present application should be included in the scope of protection of the present application.

1. A display panel, wherein the display panel comprises an active area and a peripheral area surrounding the active area, the active area comprises a light-transmitting active area, and a first active area located on at least one side of the light-transmitting active area along a first direction and a second active area located on at least one side of the light-transmitting active area along a second direction, the first direction and the second direction intersect, and light transmittance of the light-transmitting active area is greater than light transmittance of the active area; the display panel further comprises:
a substrate;
a plurality of first light-emitting elements and a plurality of first pixel circuits, located on a side of the substrate and located in the first active area and the second active area, wherein the plurality of first pixel circuits are configured for driving the plurality of first light-emitting elements to emit light, and orthographic projections of the plurality of first pixel circuits on the substrate at least partially overlap with orthographic projections of the plurality of first light-emitting elements on the substrate;
a plurality of second pixel circuits, located on the side of the substrate, and located in the first active area;
a plurality of second light-emitting elements, located on the side of the substrate, and located in the light-transmitting active area, wherein the plurality of second pixel circuits are configured for driving the plurality of second light-emitting elements to emit light;
a plurality of conductive wires, located on the side of the substrate and located in the first active area, wherein the plurality of conductive wires connect the plurality of second pixel circuits and the plurality of second light-emitting elements; and
a plurality of compensation wirings, located on the side of the substrate and located in the second active area, wherein orthographic projections of the plurality of compensation wirings on the substrate overlap with the orthographic projections of the plurality of first pixel circuits on the substrate.

2. The display panel according to claim 1, wherein lengths of the plurality of compensation wirings in the first direction decrease sequentially along the second direction away from the light-transmitting active area.

3. The display panel according to claim 2, wherein a length difference between adjacent compensation wirings among the plurality of compensation wirings is equal.

4. The display panel according to claim 1, wherein lengths of the plurality of compensation wirings in the first direction are equal.

5. The display panel according to claim 1, wherein the display panel further comprises at least one flat layer located on a side of the plurality of first pixel circuits and the plurality of second pixel circuits away from the substrate;
the plurality of compensation wirings located on a side of the at least one flat layer away from the substrate; and
the plurality of first light-emitting elements and the plurality of second light-emitting elements located on a side of the plurality of compensation wirings away from the substrate.

6. The display panel according to claim 5, wherein the at least one flat layer comprises three flat layers comprising a first flat layer, a second flat layer and a third flat layer; the first flat layer, the second flat layer and the third flat layer are arranged in stacked along a direction away from the substrate; and
the plurality of compensation wirings are located on a side of the first flat layer away from the substrate, located on a side of the second flat layer away from the substrate, and located on a side of the third flat layer away from the substrate, respectively.

7. The display panel according to claim 6, wherein shortest distances from an orthographic projection of a compensation wiring located on the side of the first flat layer away from the substrate on the substrate, an orthographic projection of a compensation wiring located on the side of the second flat layer away from the substrate on the substrate, and an orthographic projection of a compensation wiring located on the side of the third flat layer away from the substrate on the substrate to the light-transmitting active area decrease sequentially; or
the shortest distances from the orthographic projection of the compensation wiring located on the side of the first flat layer away from the substrate on the substrate, the orthographic projection of the compensation wiring located on the side of the second flat layer away from the substrate on the substrate, and the orthographic projection of the compensation wiring located on the side of the third flat layer away from the substrate on the substrate to the light-transmitting active area increase sequentially.

8. The display panel according to claim 7, wherein a quantity of compensation wirings located on the side of the first flat layer away from the substrate, a quantity of compensation wirings located on the side of the second flat layer away from the substrate, and a quantity of compensation wirings located on the side of the third flat layer away from the substrate are equal.

9. The display panel according to claim 6, wherein lengths, in the first direction, of compensation wirings arranged on a side of a same flat layer away from the substrate are equal; and
lengths, in the first direction, of compensation wirings arranged on sides of different flat layers away from the substrate decrease sequentially along the second direction away from the light-transmitting active area.

10. The display panel according to claim 1, wherein a spacing between two adjacent compensation wirings among the plurality of compensation wirings increases sequentially along the second direction away from the light-transmitting active area.

11. The display panel according to claim 1, wherein each compensation wiring among the plurality of compensation wirings comprises a plurality of line segment wirings, and a spacing between any two adjacent line segment wirings in a same compensation wiring is equal.

12. The display panel according to claim 1, wherein the orthographic projections of the plurality of compensation wirings on the substrate are located between the orthographic projections of the plurality of first light-emitting elements on the substrate; or
the orthographic projections of the plurality of compensation wirings on the substrate overlap with the orthographic projections of the plurality of first light-emitting elements on the substrate.

13. The display panel according to claim 1, wherein the plurality of compensation wirings are arranged in parallel in the first direction.

14. The display panel according to claim 1, wherein the plurality of compensation wirings are made of transparent indium tin oxide.

15. The display panel according to claim 1, wherein the first active area is located on two sides of the light-transmitting active area along the first direction, and the second active area is located on two sides of the light-transmitting active area along the second direction; and
the plurality of compensation wirings are located in the second active area on the two sides of the light-transmitting active area.

16. The display panel according to claim 15, wherein lengths, in the first direction, of compensation wirings in the second active area located on any one side of the light-transmitting active area decrease sequentially along the second direction away from the light-transmitting active area.

17. The display panel according to claim 16, wherein the plurality of conductive wires are located in the first active area on the two sides of the light-transmitting active area.

18. The display panel according to claim 16, wherein the light-transmitting active area has a symmetrical axis along the first direction, and the plurality of compensation wirings respectively located on the two sides of the light-transmitting active area along the second direction are symmetrically arranged with respect to the symmetrical axis.

19. A display device, comprising the display panel according to claim 1.

20. The display device according to claim 19, wherein the display device further comprises a sensor located on a side of a non-display surface of the display panel, and an orthographic projection of the sensor on the display panel overlaps with an orthographic projection of the light-transmitting active area of the display panel on the display panel.
